(19) United States
(12) Patent Application Publication
(10) Pub. No.: US 2023/0185038 A1
(43) Pub. Date: Jun. 15, 2023

(54) OPTO-ELECTRIC HYBRID BOARD

(71) Applicant: NITTO DENKO CORPORATION, Ibaraki-shi, Osaka (JP)

(72) Inventors: Naoyuki Tanaka, Ibaraki-shi (JP); Seiki Teraji, Ibaraki-shi (JP); Naoto Konegawa, Ibaraki-shi (JP); Koya Osuka, Ibaraki-shi (JP)

(73) Assignee: NITTO DENKO CORPORATION, Ibaraki-shi, Osaka (JP)

(21) Appl. No.: 17/925,927

(22) PCT Filed: Apr. 27, 2021
(86) PCT No.: PCT/JP2021/016733

§ 371 Date: Nov. 17, 2022

(30) Foreign Application Priority Data
May 22, 2020 (JP) 2020-089898

(51) Int. Cl. G02B 6/42; H05K 1/02; H05K 1/18

(52) U.S. Cl. CPC G02B 6/4281; G02B 6/4214; H05K 1/0274; H05K 1/0218; H05K 1/0281; H05K 1/189; H05K 2201/10121

(57) ABSTRACT

An opto-electric hybrid board that achieves sufficiently lower noise for signal transmission, is less prone to cause warpage during the mounting of various elements, and has high-speed communication properties, an opto-electric hybrid board α including: an electric circuit board 1; an optical waveguide 2 formed in a stacked manner on a first surface 1a of the electric circuit board 1; and a reinforcement plate 3 for reinforcing the electric circuit board 1, wherein a surface of the optical waveguide 2 on the opposite side from a surface thereof contacting the first surface 1a of the electric circuit board 1 is covered with the reinforcement plate 3.

### TECHNICAL FIELD

The present disclosure relates to an opto-electric hybrid board capable of optical signal transmission and electric signal transmission and, more particularly, to an opto-electric hybrid board capable of suppressing warpage due to heating and having high-speed communication properties with low noise.

### BACKGROUND ART

With the increase in the amount of transmission information, opto-electric hybrid boards in which optical interconnect lines are used in addition to electrical interconnect lines have been used in recent electronic devices and the like. However, there have been industry demands for development of products capable of transmitting more information (signals) more quickly. In view of the aforementioned situations, lower noise for signal transmission has also been required. To meet these requirements, there has been proposed a flexible opto-electric hybrid board disclosed, for example, in PTL 1.

Unfortunately, the flexible opto-electric hybrid board disclosed in PTL 1 prevents degradation of optical coupling efficiency between an optical waveguide and the outside, but presents a problem in that lower noise for signal transmission is not sufficient. In addition, the opto-electric hybrid board is sometimes exposed to elevated temperatures (e.g., 260° C.) during the mounting of various elements. In this process, there arises another problem in that warpage is prone to occur in the opto-electric hybrid board itself.

### RELATED ART DOCUMENT

### Patent Document

PTL 1: JP-A-2012-42731

### SUMMARY

In view of the foregoing, the present disclosure provides an opto-electric hybrid board that achieves sufficiently lower noise for signal transmission, is less prone to cause warpage during the mounting of various elements, and has high-speed communication properties.

To accomplish the aforementioned object, the present disclosure provides the following [1] to [5].

[1] An opto-electric hybrid board comprising: an electric circuit board; an optical waveguide formed in a stacked manner on a first surface of the electric circuit board; and a reinforcement plate for reinforcing the electric circuit board, wherein a surface of the optical waveguide on the opposite side from a surface thereof contacting the first surface of the electric circuit board is covered with the reinforcement plate.

[2] The opto-electric hybrid board according to [1], wherein the electric circuit board has a second surface mountable for various elements.

[3] The opto-electric hybrid board according to [1] or [2], wherein the reinforcement plate includes a laminate comprised of a plurality of layers, and at least one of the layers contains copper.

[4] The opto-electric hybrid board according to [3], wherein the at least one layer containing copper in the laminate has a thickness of not less than 2 μm.

[5] The opto-electric hybrid board according to any one of [1] to [4], wherein the electric circuit board has a second surface partially covered with the reinforcement plate.

The present inventors have diligently made studies to solve the aforementioned problem. As a result, the present inventors have found that the opto-electric hybrid board comprising: the electric circuit board: the optical waveguide formed in a stacked manner on the first surface of the electric circuit board; and the reinforcement plate for reinforcing the electric circuit board, wherein the surface of the optical waveguide which is not in contact with the electric circuit board is covered with the reinforcement plate not only has high-speed communication properties but also is capable of sufficiently lowering noise for signal transmission and of suppressing the occurrence of warpage during the mounting of various elements.

According to the present disclosure, the opto-electric hybrid board comprises: the electric circuit board; the optical waveguide formed in a stacked manner on the first surface of the electric circuit board; and the reinforcement plate for reinforcing the electric circuit board, wherein the surface of the optical waveguide on the opposite side from the surface thereof contacting the first surface of the electric circuit board is covered with the reinforcement plate. This sufficiently suppresses noise coming from outside on the optical waveguide side to electrical circuitry. Also, the electric circuit board is reinforced by the reinforcement plate. This suppresses the occurrence of warpage of the opto-electric hybrid board itself even when the opto-electric hybrid board is exposed to elevated temperature (e.g., 260° C.) during the mounting of various elements. Therefore, the opto-electric hybrid board of the present disclosure is excellent in reliability and in high-speed communication properties.

### BRIEF DESCRIPTION OF DRAWINGS

FIG. 1 is a schematic vertical section of an opto-electric hybrid board according to one embodiment of the present disclosure.

FIG. 2 is a partially enlarged view of the vertical section of the aforementioned opto-electric hybrid board.,

FIG. 3 is a view showing a state of a configuration of the aforementioned opto-electric hybrid board as viewed from a back surface side.

FIGS. 4A, 4B, and 4C are views illustrating modifications of the aforementioned opto-electric hybrid board.

FIGS. 5A to 5D are views illustrating a method of manufacturing the aforementioned opto-electric hybrid board.

FIGS. 6A and 6B are views illustrating the method of manufacturing the aforementioned opto-electric hybrid board.

FIGS. 7A and 7B are views illustrating the method of manufacturing the aforementioned opto-electric hybrid board.

FIG. 8 is a view illustrating a state of various elements mounted on the aforementioned opto-electric hybrid board.

FIG. 9 is a view illustrating a modification of the aforementioned opto-electric hybrid board.

### DESCRIPTION OF EMBODIMENTS

In describing the present disclosure, specific examples will be given. However, the present disclosure is not limited to the following description without departing from the spirit and scope of the present disclosure, and may be implemented with appropriate changes.

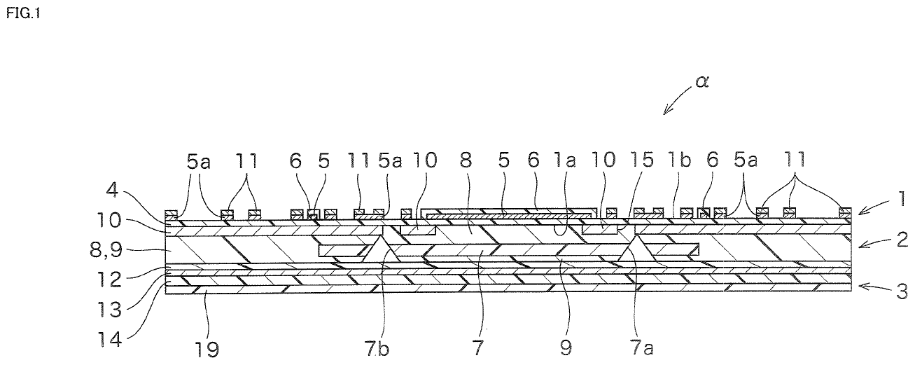

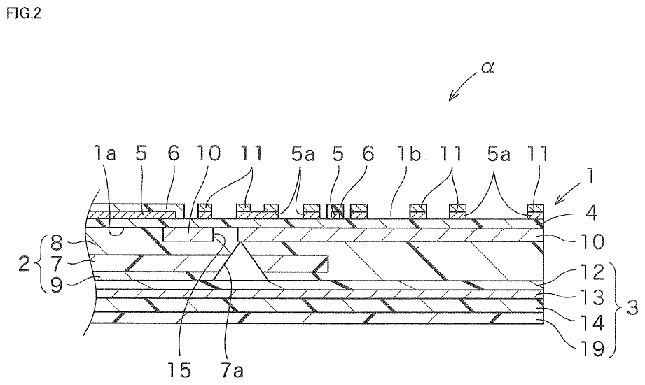

FIG. 1 is a view showing a vertical section of an opto-electric hybrid board α taken in a longitudinal direction according to one embodiment of the present disclosure, and FIG. 2 is a partially enlarged view thereof. This opto-electric hybrid board α includes: an electric circuit board 1 with electrical interconnect lines 5 formed on a front surface of an insulative layer 4; an optical waveguide 2 formed in a stacked manner on a first surface 1a of the electric circuit board 1; and a reinforcement plate 3 for reinforcing the electric circuit board 1.

The electric circuit board 1 and the optical waveguide 2 will be described first, and the reinforcement plate 3 will be then described.

[Electric Circuit Board 1]

As shown in FIG. 2, the aforementioned electric circuit board 1 is configured such that the electrical interconnect lines 5 including mounting pads 5a for various elements, grounding electrodes (not shown), and the like are formed on the front surface of the insulative layer 4 having light permeability and made of a resin such as polyimide, and such that the electrical interconnect lines 5 excluding the mounting pads 5a and the like are insulated and protected by a coverlay 6 made of the same resin as the insulative layer 4, such as polyimide. A front surface of the electrical interconnect lines 5 not covered with the coverlay 6 is covered with an electroplated layer 11 made of gold, nickel, or the like.

[Optical Waveguide 2]

The optical waveguide 2 formed in a stacked manner on a back surface of the insulative layer 4 (the first surface 1a of the electric circuit board 1) includes an under cladding layer 8, a core 7 for an optical path formed in a predetermined pattern on a front surface of the under cladding layer 8 (a lower surface as seen in FIG. 1), and an over cladding layer 9 integral with the front surface of the under cladding layer 8 while covering the core 7. The core 7 has a refractive index higher than those of the under cladding layer 8 and the over cladding layer 9. A metal layer 10 for reinforcement is provided in portions lying between the electric circuit board 1 and the optical waveguide 2 where a certain level of strength is required, such as portions corresponding to the mounting pads 5a on which various elements are to be mounted.

Portions of the optical waveguide 2 which correspond to optical element mounting locations of the opto-electric hybrid board α are in the form of inclined surfaces at 45 degrees with respect to the direction of extension of the core 7. The inclined surfaces serve as light reflecting surfaces (7a and 7b) which function to change the direction of light propagated in the core 7 by 90 degrees to cause the light to enter a light-receiving portion of an optical element or to change the direction of light exiting a light-emitting portion of an optical element by 90 degrees to cause the light to enter the core 7.

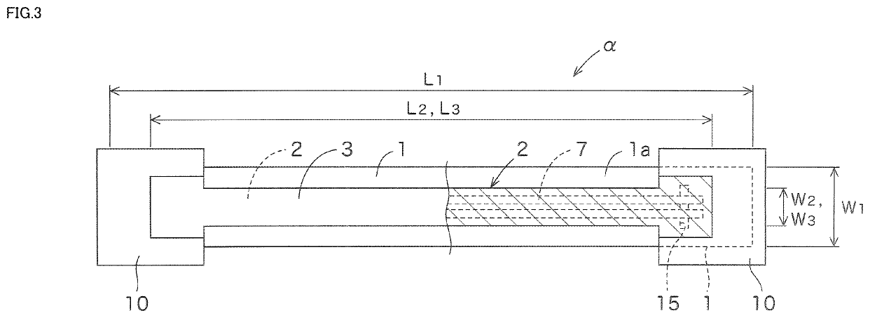

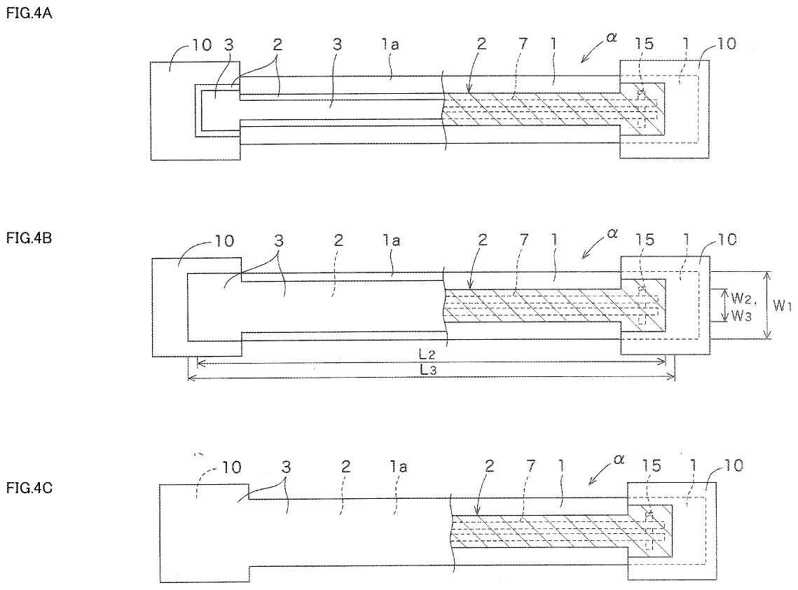

In the opto-electric hybrid board α of the present disclosure, a surface of the optical waveguide 2 on the opposite side from a surface thereof contacting the first surface 1a of the electric circuit board 1 is covered with the reinforcement plate 3, as shown in FIG. 3 which depicts a configuration of the opto-electric hybrid board α as viewed from a back surface side. This is a striking feature of the present disclosure. In FIG. 3, the right half of the reinforcement plate 3 is broken to show the underlying structure, and the optical waveguide 2 is shaded with diagonal lines (the same applies to FIGS. 4A, 4B, and 4C) for the sake of an easier understanding of a positional relationship between the optical waveguide 2 and the reinforcement plate 3.

[Reinforcement Plate 3]

As shown in FIG. 2, the reinforcement plate 3 includes a laminate comprised of an anisotropic conductive adhesive layer 12, a shield layer 13 made of a thin film of metal, a protective layer 14 made of an insulating resin, and a transfer film 19 made of a resin such as polyethylene terephthalate. The reinforcement plate 3 is attached to the surface of the optical waveguide 2 on the opposite side from the surface thereof contacting the electric circuit board 1 with the use of the adhesive strength of the anisotropic conductive adhesive layer 12.

The reinforcement plate 3 is attached, for example, by the application of pressure and heat using hot pressing. The aforementioned hot pressing is preferably performed, for example, under conditions of a press temperature of 70 to 180° C., a press pressure of 0.1 to 5.0 kgf1cm², and a press time of 1 to 90 minutes in terms of an improvement in adhesion.

The aforementioned anisotropic conductive adhesive layer 12 is made of a conductive resin composition cured, and has a thickness preferably in the range of 1 to 50 μm and more preferably in the range of 3 to 30 μm.

The aforementioned shield layer 13 is made of a thin film of metal, and has a thickness preferably in the range of 0.1 to 50 μm and more preferably in the range of 2 to 10 μm. Examples of the aforementioned metal used herein include copper, silver, aluminum, and nickel. Copper and aluminum are preferably used, and copper is more preferably used.

The aforementioned protective layer 14 is made of an insulating resin, and has a thickness preferably in the range of 2 to 50 μm and more preferably in the range of 3 to 20 μm.

The aforementioned transfer film 19 is made of a resin such as PET, and has a thickness preferably in the range of 2 to 100 μm and more preferably in the range of 20 to 60 μm.

Next, a method of manufacturing the aforementioned opto-electric hybrid board α will be described.

### [Formation of Electric Circuit Board 1]

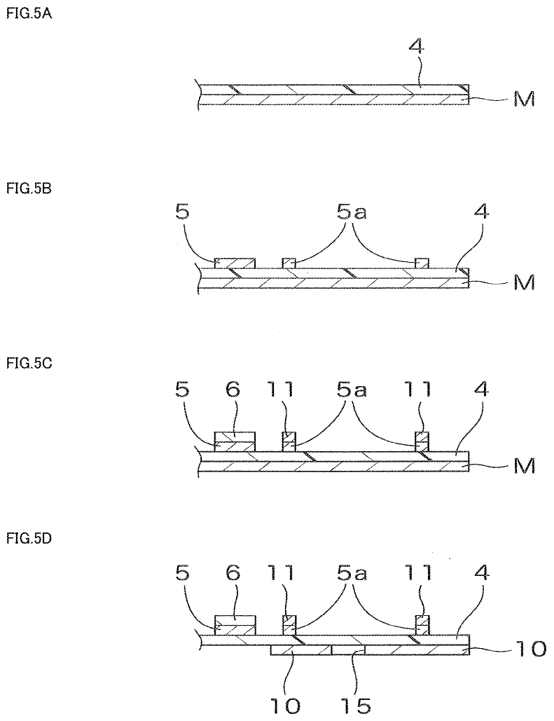

First, a metal sheet material M (with reference to FIG. 5A) for the formation of the metal layer 10 is prepared. Examples of a material for the formation of the metal sheet material M include stainless steel and 42 alloy (an alloy of iron and nickel, wherein a content of the nickel is 42%). In particular, stainless steel is preferable from the viewpoint of dimensional accuracy and the like. The metal sheet material M (the metal layer 10) has a thickness in the range of 5 to 100 μm, for example.

Next, as shown in FIG. 5A, a photosensitive insulating resin is applied to a front surface of the metal sheet material M to form the insulative layer 4 having a predetermined pattern by a photolithographic process. Examples of a material for the formation of the insulative layer 4 include: synthetic resins such as polyimide, polyether nitrile, polyether sulfone, polyethylene terephthalate, polyethylene naphthalate, and polyvinyl chloride; and silicone sol-gel materials. The insulative layer 4 has a thickness in the range of 1 to 100 μm, for example.

Next, as shown in FIG. 5B, the electrical interconnect lines 5 and the mounting pads 5a are formed by a semi-additive process or a subtractive process, for example. The electrical interconnect lines 5 and the mounting pads 5a have a thickness preferably in the range of 1 to 30 μm, for example.

Next, as shown in FIG. 5C, a photosensitive insulating resin including a polyimide resin or the like is applied to portions of the electrical interconnect lines 5 to thereby form the coverlay 6 by a photolithographic process. The coverlay 6 has a thickness preferably in the range of 1 to 30 μm, for example. The electroplated layer 11 is formed on portions of the mounting pads 5a and the like where the coverlay 6 is not formed. In this manner, the electric circuit board 1 (with reference to FIGS. 1 to 3) is formed on the front surface of the metal sheet material M. Preferably, a second surface (a surface on the side where the optical waveguide 2 is not formed) of the electric circuit board 1 is mountable for various elements as mentioned above.

[Formation of Metal Layer 10]

Thereafter. as shown in FIG. 50, etching or the like is performed on the metal sheet material M to impart a predetermined shape including a through hole 15 to the metal sheet material M. In this manner, the metal sheet material M is formed into the metal layer 10.

[Formation of Optical Waveguide 2]

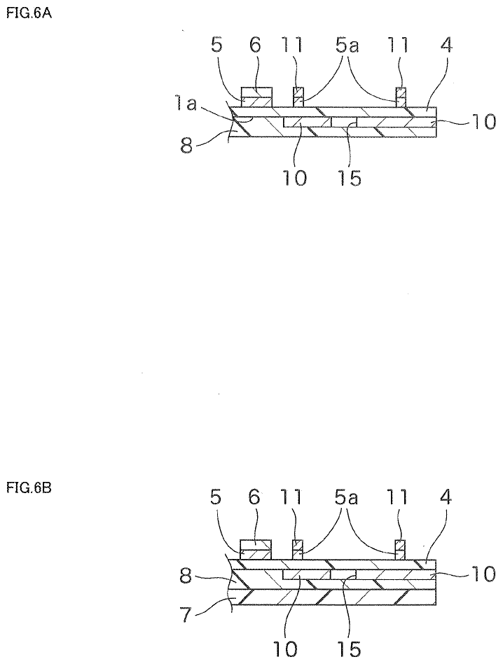

For the formation of the optical waveguide 2 (with reference to FIG. 1) on the back surface (the first surface 1a) of the electric circuit board 1, a photosensitive resin which is a material for the formation of the under cladding layer 8 is initially applied to the back surface (the first surface 1a; or the lower surface as seen in the figure) of the electric circuit board 1, and is formed into the under cladding layer 8 by a photolithographic process, as shown in FIG. 6A. The under cladding layer 8 has a thickness (a thickness as measured from a back surface of the metal layer 10) in the range of 1 to 80 μm, for example. It should be noted that the back surface of the electric circuit board 1 is positioned to face upward when the optical waveguide 2 is formed (when the aforementioned under cladding layer 8, the core 7 to be described later, and the over cladding layer 9 to be described later are formed).

Next, as shown in FIG. 6B, a photosensitive dry film which is a material for the formation of the core 7 is laminated to or a photosensitive resin is applied to the front surface (the lower surface as seen in the figure) of the under cladding layer 8 to form the core 7 by a photolithographic process. The core 7 has a thickness in the range of 2 to 80 μm, for example. The refractive index of the core 7 is higher than those of the under cladding layer 8 and the over cladding layer 9.

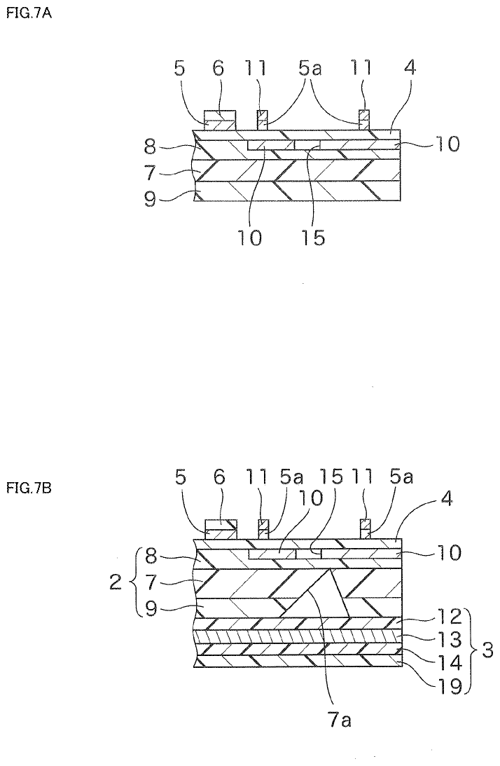

Then, as shown in FIG. 7A, a material for the formation of the over cladding layer 9 is applied to the front surface (the lower surface as seen in the figure) of the under cladding layer 8 so as to cover the core 7 to form the over cladding layer 9 by a photolithographic process. The over cladding layer 9 has a thickness [a thickness as measured from the top surface (the lower surface as seen in the figure) of the core 7] in the range of 2 to 50 μm, for example. An example of the material for the formation of the over cladding layer 9 includes a photosensitive resin similar to that for the under cladding layer 8.

Thereafter. as shown in FIG. 7B, a specific portion of the core 7 together with the under cladding layer 8 and the over cladding layer 9 is formed into an inclined surface inclined at 45 degrees with respect to the direction of extension (the longitudinal direction) of the core 7, for example, by dicing or laser machining. The specific portion of the core 7 which is positioned at the inclined surface serves as a light reflecting surface (a mirror surface 7a). In this manner, the optical waveguide 2 including the mirror surface 7a is formed on the back surface of the metal layer 10.

[Formation of Reinforcement Plate 3]

Next, a laminate including the anisotropic conductive adhesive layer 12, the shield layer 13, the protective layer 14, and the transfer film 19 which are laminated together in the order named is prepared as the reinforcement plate 3 and is cut to a size that covers the entire surface of the optical waveguide 2. The cut laminate is overlaid on the entire surface of the optical waveguide 2 (the entire surface on the opposite side from the surface contacting the first surface 1a of the electric circuit board 1) so that the anisotropic conductive adhesive layer 12 is in contact with the entire surface of the optical waveguide 2, and is integrated therewith using hot pressing. The aforementioned hot pressing may be performed using a single-layer press or a multiplaten press. The conditions for the aforementioned hot pressing may be vacuum or atmospheric pressure. The temperature for the aforementioned hot pressing is preferably in the range of 70 to 150° C. and more preferably approximately 120° C. The pressing time is preferably in the range of 0.1 to 30 minutes and more preferably in the range of 1 to 3 minutes.

The area of the reinforcement plate 3 is preferably not less than 50% of the area of the electric circuit board 1, more preferably not less than 70% thereof, further preferably not less than 90% thereof, and still further preferably 100% thereof.

In addition, the area of the reinforcement plate 3 is preferably not less than 60% of the area of the optical waveguide 2, more preferably not less than 80% thereof, further preferably not less than 90% thereof, and still further preferably 100% thereof.

In this manner, the opto-electric hybrid board α is obtained in which the entire surface of the optical waveguide 2 on the opposite side from the surface thereof contacting the electric circuit board 1 is covered with the reinforcement plate 3 (the cut laminate).

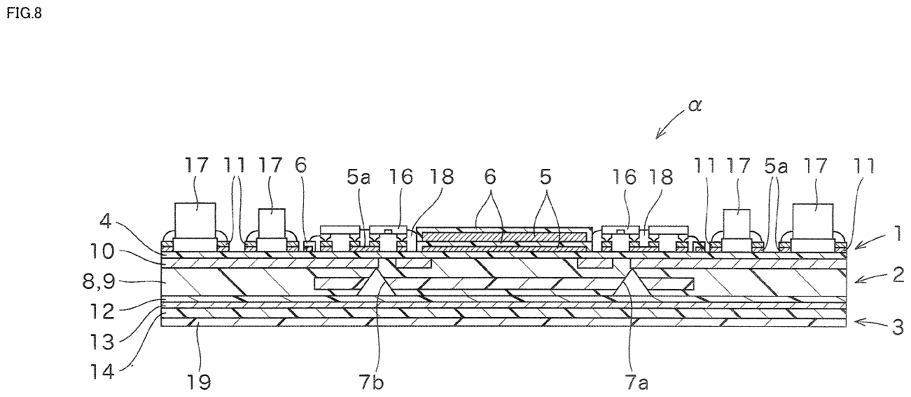

As shown in FIG. 8, for example, the opto-electric hybrid board α has an end portion with a connector attached thereto (not shown). Optical elements 16 and ICs 17 are generally mounted on the mounting pads 5a, with the electroplated layer 11 therebetween, at an elevated temperature (e.g., 260° C.). The reference numeral 18 designates a sealing resin.

This configuration reduces noise coming from outside on the optical waveguide 2 side to the electrical interconnect lines 5 to ensure sufficient high-speed communication properties because the entire surface of the optical waveguide 2 on the opposite side from the surface thereof contacting the first surface 1a of the electric circuit board 1 is covered with the reinforcement plate 3. Also, the provision of the reinforcement plate 3 on the first surface 1a (the optical waveguide 2) side of the electric circuit board 1 provides excellent mountability without adversely affecting the mounting of various elements. Further, the reinforcement plate 3 covers the entire surface of the optical waveguide 2, and has an area that is not less than 50% of the area of the electric circuit board 1. This makes warpage less prone to occur during the mounting of various elements, and achieves an improvement in heat resistance.

It should be noted that the area of the electric circuit board 1 and the area of the optical waveguide 2 do not include the area of a portion where only the metal layer 10 is present.

In the aforementioned embodiment, the entire surface of the optical waveguide 2 is covered with the reinforcement plate 3, as shown in FIG. 3. However, as shown in FIG. 4A, the reinforcement plate 3 need not necessarily cover the entire surface of the optical waveguide 2 if the reinforcement plate 3 covers at least a portion of the optical waveguide 2 which encompasses the core 7 portion. However, the reinforcement plate 3 preferably covers a flexible portion of the optical waveguide 2. The flexible portion refers to a portion formed by the core 7, the under cladding layer 8, and the over cladding layer 9, and not having a hard member such as the metal layer 10.

The reinforcement plate 3 may cover not only the entire surface of the optical waveguide 2 but also part of the first surface 1a of the electric circuit board 1, as shown in FIG. 4B. The covering of the reinforcement plate 3 which extends to the electric circuit board 1 as shown in FIG. 4B tends to improve strength and communication properties and to reduce noise.

The ratio (W₃/W₂) of the width W₃ of the reinforcement plate 3 to the width W₂ of the optical waveguide 2 is preferably in the range of 0.4 to 2.0, more preferably in the range of 0.6 to 1.7, and further preferably in the range of 0.8 to 1.2. The ratio (L₃/L₂) of the length L₃ of the reinforcement plate 3 to the length L₂ of the optical waveguide 2 is preferably in the range of 0.6 to 2.0, more preferably in the range of 0.8 to 1.5, and further preferably in the range of 0.9 to 1.1. These ratios within the aforementioned ranges tend to provide a more excellent balance between costs and reductions in noise and in amount of warpage. if the width W₂ of the optical waveguide 2 varies in the longitudinal direction, the width of the aforementioned flexible portion is defined as the width W₂ of the optical waveguide 2.

The reinforcement plate 3 may cover not only the entire surface of the optical waveguide 2 but also the entire first surface 1a of the electric circuit board 1, as shown in FIG. 4C. The covering state of the reinforcement plate 3 as shown in FIG. 4C tends to further improve strength and communication properties. to reduce noise, and to further reduce the amount of warpage.

The reinforcement plate 3 includes the laminate in the aforementioned embodiment, but is not limited to a laminate. For example, a thin metal film may be formed directly on the insulative layer 4 or a paste having an electromagnetic wave shielding function obtained by dispersing metal particles in a resin may be applied directly on the insulative layer 4 to form an electromagnetic wave shielding layer. However, the reinforcement plate 3 including the laminate is preferable in making warpage less prone to occur during the mounting of various elements and in achieving an improvement in heat resistance. The aforementioned metal may be the same metal as the shield layer 13, and the suitable thickness of the aforementioned metal is also the same.

The laminate of the reinforcement plate 3 has a layer comprised of a thin metal film in the aforementioned embodiment, but need not necessarily have a thin metal film. However, the aforementioned laminate having a thin metal film layer with a thickness of not less than 2 μm tends to reduce the amount of warpage.

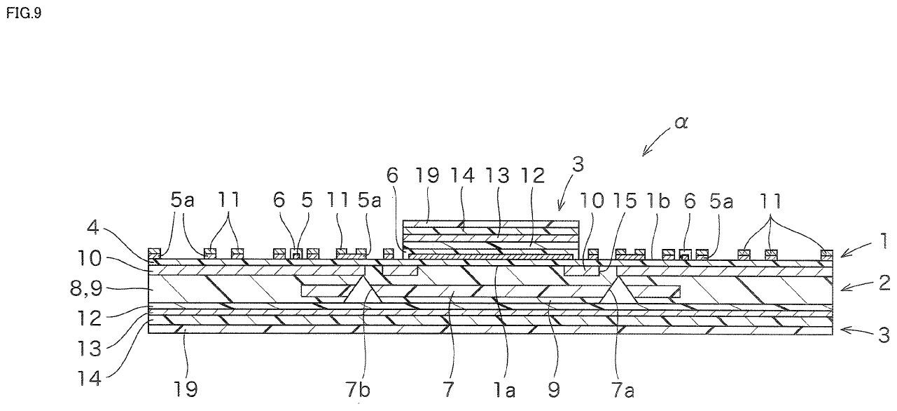

Further, the reinforcement plate 3 is provided only on the first surface 1a side (the optical waveguide 2 side) of the electric circuit board 1 in the aforementioned embodiment, but may also be provided on a second surface 1b side of the electric circuit board 1, as shown in FIG. 9. At this time, the reinforcement plate 3 is preferably provided on the second surface 1b in a location where various elements are not to be mounted (e.g., on the coverlay 6). Also, the reinforcement plate 3 provided on the first surface 1a side of the electric circuit board 1 and the reinforcement plate 3 provided on the second surface 1b side thereof may be of the same or different types. However, the use of the same type of reinforcement plate 3 tends to make warpage less prone to occur when exposed to elevated temperatures because the materials having the same linear expansion coefficient are provided on both surfaces of the electric circuit board 1.

### EXAMPLES

Although the present disclosure will be described hereinafter in further detail using examples, the examples may be modified as appropriate without departing from the spirit and scope of the present disclosure. Therefore, the scope of the present disclosure should not be interpreted as limited by the specific examples illustrated below.

First, materials (materials for the formation of the optical waveguide 2, and the reinforcement plate 3) to be described below were prepared.

<Materials for Formation of Optical Waveguide 2>

(1) The following components were mixed and prepared as a material for the formation of the core 7.

[Epoxy Resin]

30 parts by weight of VG3101L (available from Printec Corporation).

20 parts by weight of YX-7180BH40 (available from Mitsubishi Chemical Corporation).

30 parts by weight of jER-1002 (available from Mitsubishi Chemical Corporation).

20 parts by weight of OGSOL PG-100 (available from Osaka Gas Chemicals Co., Ltd.).

[Photo-Cation Polymerization Initiator]

2 parts by weight of CPI-101A (available from San-Apro Ltd.).

[Antioxidant]

0.5 parts by weight of Songnox1010 (available from Kyodo Chemical Co., Ltd.).

1.5 parts by weight of HCA (available from Sanko Co., Ltd.).

(2) The following components were mixed and prepared as a material for the formation of the under cladding layer 8 and the over cladding layer 9.

[Epoxy Resin]

20 parts by weight of VG3101L (available from Printec Corporation).

20 parts by weight of YX-7180BH40 (available from Mitsubishi Chemical Corporation).

30 parts by weight of jER-1002 (available from itsubishi Chemical Corporation).

30 parts by weight of EHPE3150 (available from Daicel Corporation).

[Photo-Cation Polymerization Initiator]

2 parts by weight of CPI-101A (available from San-Apra Ltd.).

[Antioxidant]

0.5 parts by weight of Songnox1010 (available from Kyodo Chemical Co., Ltd.).

1.5 parts by weight of HCA (available from Sanko Co., Ltd.).

<Reinforcement Plate 3>

Reinforcement Plate A: SF-PC3300-C (available from Tatsuta Electric Wire & Cable Co., Ltd.).

Reinforcement Plate B: SF-PC3100-C (available from Tatsuta Electric Wire & Cable Co., Ltd.).

Reinforcement Plate C: SF-PC5600-C (available from Tatsuta Electric Wire & Cable Co., Ltd.).

Reinforcement Plate D: SF-PC5900-C (available from Tatsuta Electric Wire & Cable Co., Ltd.).

Reinforcement Plate E: SF-PC6000-U1 (available from Tatsuta Electric Wire & Cable Co., Ltd.).

The aforementioned materials were used to produce Examples 1 to 7 and Comparative Example 1 in a manner to be described below.

### Example 1

As described in the aforementioned embodiment, the electric circuit board 1 having a width W₁ of 8 mm and a length L₁ of 260 mm shown in FIG. 3 was prepared, and the optical waveguide 2 having a width W₂ of 3 mm and a length L₂ of 250 mm was formed on the first surface 1a of this electric circuit board 1 so that the centers of the widths and lengths of the electric circuit board 1 and the optical waveguide 2 coincided with each other as seen in plan view.

Next, the aforementioned reinforcement plate B as the reinforcement plate 3 was cut to a size (a width W₃ of 3 mm and a length L₃ of 250 mm) that covered the entire surface of the optical waveguide 2. This cut piece was overlaid so as to cover the optical waveguide 2. The cut piece and the optical waveguide 2 were integrated together by heating and pressing under pressure, whereby an intended opto-electric hybrid board was produced.

The electric circuit board 1 includes an electrical circuit formed with copper on a polyimide having a thickness of 10 μm. The optical waveguide 2 is formed to include the under cladding layer 8 having a thickness of 25 μm, the over cladding layer 9 having a thickness of 30 μm, and the core having a thickness of 40 μm.

### Example 2

An intended opto-electric hybrid board was produced in the same manner as in Example 1 except that the reinforcement plate was changed to the aforementioned reinforcement plate A.

### Example 3

An intended opto-electric hybrid board was produced in the same manner as in Example 2 except that a portion of the second surface 1b of the electric circuit board 1 where various elements were not to be mounted was also covered with the reinforcement plate A.

### Example 4

An intended opto-electric hybrid board was produced in the same manner as in Example 3 except that a portion of the second surface 1b of the electric circuit board 1 where various elements were not to be mounted was covered with the reinforcement plate C.

### Example 5

An intended opto-electric hybrid board was produced in the same manner as in Example 1 except that the reinforcement plate was changed to the aforementioned reinforcement plate C.

### Example 6

An intended opto-electric hybrid board was produced in the same manner as in Example 1 except that the reinforcement plate was changed to the aforementioned reinforcement plate D.

### Example 7

An intended opto-electric hybrid board was produced in the same manner as in Example 1 except that the reinforcement plate was changed to the aforementioned reinforcement plate E.

### Comparative Example 1

An intended opto-electric hybrid board was produced in the same manner as in Example 1 except that the reinforcement plate was not used. In other words. Comparative Example 1 corresponds to a conventional product in which the reinforcement plate 3 is not included in the configuration.

Measurements of the amount of warpage were performed on the opto-electric hybrid boards of Examples 1 to 7 and Comparative Example 1 in a manner to be described below. The measured values were evaluated in accordance with criteria to be described below, and were listed together in TABLE 1 below.

Measurements of element mountability were performed on the opto-electric hybrid boards of Examples 1 to 7 and Comparative Example 1 in a manner to be described below.

Regarding noise from the optical waveguide side (noise coming from outside on the optical waveguide 2 side to the electrical interconnect lines 5) and noise from the electric circuit board side (noise coming from outside of the electric circuit board 1 to the electrical interconnect lines 5), the reinforcement plate 3 itself used in each Example has an electromagnetic wave shielding effect. For this reason. noise from the side where the reinforcement plate 3 was placed in the opto-electric hybrid boards of Examples 1 to 7 was evaluated as being suppressed, and was listed together in TABLE 1 below.

<Amount of Warpage>

Measurement Method

The opto-electric hybrid boards of Examples 1 to 7 and Comparative Example 1 were each placed on a horizontal surface. If a portion of each opto-electric hybrid board lifted up and separated from the horizontal surface, a distance from the horizontal surface to the farthest portion was measured and evaluated based on the measured value in reference to criteria to be described below. In other words, the greater the aforementioned distance is, the greater the amount of warpage is.

Evaluation Criteria

∘ (good): The aforementioned distance is less than 20 mm.

Δ(practicable): The aforementioned distance is not less than 20 mm and less than 50 mm.

× (poor): The aforementioned distance is not less than 50 mm.

<Element Mountability>

Optical elements were mounted on the opto-electric hybrid boards of Examples 1 to 7 and Comparative Example 1, and the shear strengths of the aforementioned optical elements were measured using a shearing tool. At this time, measurement conditions were set to a height of 80 μm from the top surface of the electrical circuit and a velocity of 100 μm/sec. As a result, arbitrary differences did not arise in shear strength of the optical elements between Examples 1 to 7 and Comparative Example 1. In other words, it was found that Examples 1 to 7 obtained shear strengths comparable to that of Comparative Example 1 (conventional product) and that there were no problems with the mountability of the optical elements in Examples 1 to 7.

TABLE 1

| | Reinforcement plate | | | | | | | | | | |
|---|---|---|---|---|---|---|---|---|---|---|---|
| | Optical waveguide side | | | | Electric circuit board side | | | | Noise from | Noise from | |
| | | | | Thickness | | | | Thickness | optical | electric | |
| | | | | of | | | | of | waveguide | circuit board | |
| | Type of | Thin metal film | | anisotropic | Type of | Thin metal film | | anisotropic | side to | side to | |
| | reinforce- | | Thick- | conductive | reinforce- | | Thick- | conductive | electrical | electrical | |
| | ment | Metal | ness | adhesive | ment | Metal | ness | adhesive | interconnect | interconnect | Amount of |
| | plate | type | (μm) | layer (μm) | plate | type | (μm) | layer (μm) | lines | lines | warpage |
| Ex. 1 | B | Cu | 2 | 9 | — | — | — | — | ∘ | x | Δ |
| Ex. 2 | A | Cu | 5.5 | 9 | — | — | — | — | ∘ | x | ∘ |
| Ex. 3 | A | Cu | 5.5 | 9 | A | Cu | 5.5 | 9 | ∘ | ∘ | ∘ |
| Ex. 4 | A | Cu | 5.5 | 9 | C | Ag | 0.1 | 17 | ∘ | ∘ | ∘ |
| Ex. 5 | C | Ag | 0.1 | 17 | — | — | — | — | ∘ | x | x |
| Ex. 6 | D | Ag | 0.1 | 5 | — | — | — | — | ∘ | x | x |
| Ex. 7 | E | — | — | 16 | — | — | — | — | ∘ | x | x |
| Comp | — | — | — | — | — | — | — | — | x | x | x |
| Ex. 1 | | | | | | | | | | | |

The aforementioned results show that the opto-electric hybrid boards of Examples 1 to 7 are reduced in noise and in amount of warpage. In particular, Examples 2 to 4 in which the reinforcement plate A is provided on the optical waveguide 2 side show that the reduction in amount of warpage is sufficiently achieved because the thickness of the thin metal film (the shield layer 13) of the reinforcement plate A is 5.5 μm. Examples 3 and 4 in which the reinforcement plate A or C is also provided on the electric circuit board 1 side (the second surface 1b of the electric circuit board 1) show that noise from the electric circuit board 1 side is also reduced.

In contrast, the opto-electric hybrid board of Comparative Example 1 shows no reduction in noise and in amount of warpage.

Although specific forms in the present disclosure have been described in the aforementioned examples, the aforementioned examples should be considered as merely illustrative and not restrictive. It is contemplated that various modifications evident to those skilled in the art could be made without departing from the scope of the present disclosure.

The opto-electric hybrid board of the present disclosure. which is capable of sufficiently lowering noise for signal transmission and is less prone to cause warpage during the mounting of various elements, is preferably used as an opto-electric hybrid board having high-speed communication properties.

### REFERENCE SIGNS LIST

1 Electric circuit board

1a First surface

2 Optical waveguide

3 Reinforcement plate

α Opto-electric hybrid board

1-5. (canceled)

6. An opto-electric hybrid board comprising:
an electric circuit board:
an optical waveguide formed in a stacked manner on a first surface of the electric circuit board; and
a reinforcement plate for reinforcing the electric circuit board,
wherein a surface of the optical waveguide on the opposite side from a surface thereof contacting the first surface of the electric circuit board is covered with the reinforcement plate.

7. The opto-electric hybrid board according to claim 6,
wherein the electric circuit board has a second surface mountable for various elements.

8. The opto-electric hybrid board according to claim 6,
wherein the reinforcement plate includes a laminate comprised of a plura y of layers, and at least one of the layers contains copper.

9. The opto-electric hybrid board according to claim 7,
wherein the reinforcement plate includes a laminate comprised of a plurality of layers, and at least one of the layers contains copper.

10. The opto-electric hybrid board according to claim 8,
wherein the at least one layer containing copper in the laminate has a thickness of not less than 2 μm.

11. The opto-electric hybrid board according to claim 9,
wherein the at least one layer containing copper in the laminate has a thickness of not less than 2 μm.

12. The opto-electric hybrid board according to claim 6,
wherein the electric circuit board has a second surface partially covered with the reinforcement plate.

13. The opto-electric hybrid board according to claim 7,
wherein the electric circuit board has the second surface partially covered with the reinforcement plate.
